(19) United States
(12) Patent Application Publication
(10) Pub. No.: US 2025/0329618 A1
(43) Pub. Date: Oct. 23, 2025

(54) SEMICONDUCTOR PACKAGE STRUCTURE AND METHOD FOR FORMING THE SAME

(71) Applicant: MEDIATEK INC., Hsinchu City (TW)

(72) Inventor: Chin-Chiang CHANG, Hsinchu City (TW)

(21) Appl. No.: 19/179,291

(22) Filed: Apr. 15, 2025

Related U.S. Application Data
(60) Provisional application No. 63/635,664, filed on Apr. 18, 2024.

(51) Int. Cl. H01L 23/495; H01L 21/768; H01L 21/78; H01L 23/00; H01L 23/48

(52) U.S. Cl. CPC H01L 23/49513; H01L 21/76898; H01L 21/78; H01L 23/481; H01L 24/29; H01L 24/32; H01L 24/48; H01L 24/73; H01L 24/83; H01L 24/85; H01L 24/92; H01L 2224/2929; H01L 2224/32245; H01L 2224/48247; H01L 2224/73265; H01L 2224/83191; H01L 2224/85986; H01L 2224/92247

(57) ABSTRACT

A semiconductor package structure and a method for forming the same are provided. The semiconductor package structure includes a semiconductor die and a conductive adhesive layer. The semiconductor die includes a semiconductor substrate, a semiconductor substrate and a through via. The semiconductor substrate has a first surface and a second surface. The semiconductor device is formed on the first surface of the semiconductor substrate. The through via is formed in such a way that it passes through the semiconductor substrate. The conductive adhesive layer is disposed on the second surface of the semiconductor substrate. The through via is coupled to the conductive adhesive layer.

### CROSS REFERENCE TO RELATED APPLICATIONS

This application claims the benefit of U.S. Provisional Application No. 63/635,664, filed on Apr. 18, 2024, the entirety of which is incorporated by reference herein.

### BACKGROUND OF THE DISCLOSURE

### Field of the Disclosure

The present disclosure relates to a semiconductor package structure and a method for forming the same, and, in particular, it relates to a semiconductor package structure having a through via in a semiconductor die and a method for forming the same.

### Description of the Related Art

The quad flat no-lead (QFN) package is known for its small size, cost-effectiveness, and good production yields. QFN packages also possess certain mechanical advantages for high-speed circuits, including improved co-planarity and heat dissipation.

The technological trends currently guiding the back-end packaging industry can be summarized with the phrase, “more functionality in a smaller space”. The functionality of these integrated circuit chips is becoming more and more complicated, leading to increased numbers of external connection pins in the leadframe package. As the pin count increases, the cost of packaging each die goes up accordingly. To avoid an undesirable increase in the size of the package attributable to the increased number of connection pins or leads, one approach is to reduce the lead pitch. However, narrowing the lead pitch results in an increase in the level of mutual inductance and mutual capacitance generated by the leads of the package. Thus, leadframe packages are typically considered to be unsuitable for high-speed semiconductor dies, which transmit signals at high speeds, since the relatively high inductance and capacitance may distort the signals that are transmitted.

Therefore, there is a strong need in this industry to provide an improved leadframe structure and leadframe package, which are cost-effective and are particularly suited for high-speed semiconductor dies, as well as being capable of improving electrical

### BRIEF SUMMARY OF THE INVENTION

An embodiment of the present disclosure provides a semiconductor package structure. The semiconductor package structure includes a semiconductor die and a conductive adhesive layer. The semiconductor die includes a semiconductor substrate, a semiconductor substrate and a through via. The semiconductor substrate has a first surface and a second surface. The semiconductor device is formed on the first surface of the semiconductor substrate. The through via is formed in such a way that it passes through the semiconductor substrate. The conductive adhesive layer is disposed on the second surface of the semiconductor substrate. The through via is coupled to the conductive adhesive layer.

An embodiment of the present disclosure provides a method for forming a semiconductor package structure. The method includes providing a semiconductor wafer. The semiconductor wafer includes a semiconductor substrate, a semiconductor device and a through via. The semiconductor substrate has a first surface and a second surface. The semiconductor device is formed on the first surface of the semiconductor substrate. The through via extends from above the first surface of the semiconductor substrate into a portion of the semiconductor substrate. The method further includes removing a portion of the semiconductor substrate from the second surface until the through via has a protruding portion that protrudes from the semiconductor substrate. The method further includes forming a conductive adhesive layer on the second surface of the semiconductor substrates.

### BRIEF DESCRIPTION OF THE DRAWINGS

The present disclosure can be more fully understood by reading the subsequent detailed description and examples with references made to the accompanying drawings, wherein:

FIG. 1 is a side view of a semiconductor package structure in accordance with some embodiments of the disclosure;

FIG. 2 is a partial enlarged cross-sectional view of FIG. 1, showing a portion of a semiconductor die and a leadframe of the semiconductor package structure of FIG. 1 in accordance with some embodiments of the disclosure;

FIG. 3 is a partial enlarged cross-sectional view of FIG. 1, showing a portion of a semiconductor die and a leadframe of the semiconductor package structure of FIG. 1 in accordance with some embodiments of the disclosure; and

FIGS. 4, 5, 6, 7, 8, 9, 10, 11, 12 and 13 are enlarged cross-sectional views of intermediate stages of forming the semiconductor package structure of FIG. 1 in accordance with some embodiments of the disclosure.

### DETAILED DESCRIPTION OF THE INVENTION

The following description is made for the purpose of illustrating the general principles of the disclosure and should not be taken in a limiting sense. The scope of the disclosure is best determined by reference to the appended claims.

There are various leadframe-based surface mount components, such as quad flat no-lead (QFN) package, advanced QFN (aQFN) package, low-profile quad flat package (LQFP) or the like. A package can be attached to a printed circuit board (PCB) by, for example, soldering it to the PCB. The attachment of the packages (i.e. packaged integrated circuit) to PCBs produces printed circuit board assemblies (PCBAs), which can be used as motherboards in computers, portable devices such as mobile phone, tablets, notebooks, etc.

Generally, a leadframe strip is populated with a plurality of leadframes. A semiconductor die or microelectronic device may be mounted on each leadframe and encapsulated with a molding compound. Leadframes are separated during singulation of the strip to create individual semiconductor packages. One type of the semiconductor packages is a flat-pack no-lead package where each terminal is exposed at a bottom and at a side of the package. Typically, the sawing process during singulation of the strip typically results in lead terminals that have at least some exposed base metal on a cut end, or flank, of each lead terminal. Typically, the aforesaid cut end is vertically flush with a sidewall surface of the package or the sidewall surface of a molding compound.

The term of quad flat no-lead or small outline no-lead package indicates that the leads do not have cantilevered leads, but flat leads, which are typically arrayed along the periphery of the packaged device. The metal of the leads may be connected by solder material to the metal of respective contact pads of an external part. QFN packages typically use a copper leadframe for the die assembly and PCB interconnection.

Embodiments provide a quad flat no-lead (QFN) type package. However, those of ordinary skill in the art will readily understand the details of the invention and that the invention is applicable to other package types.

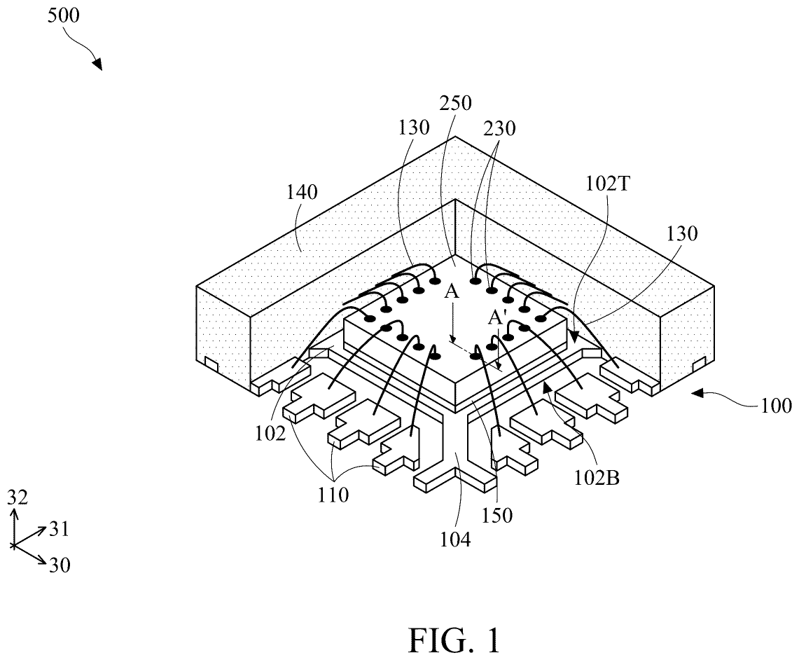

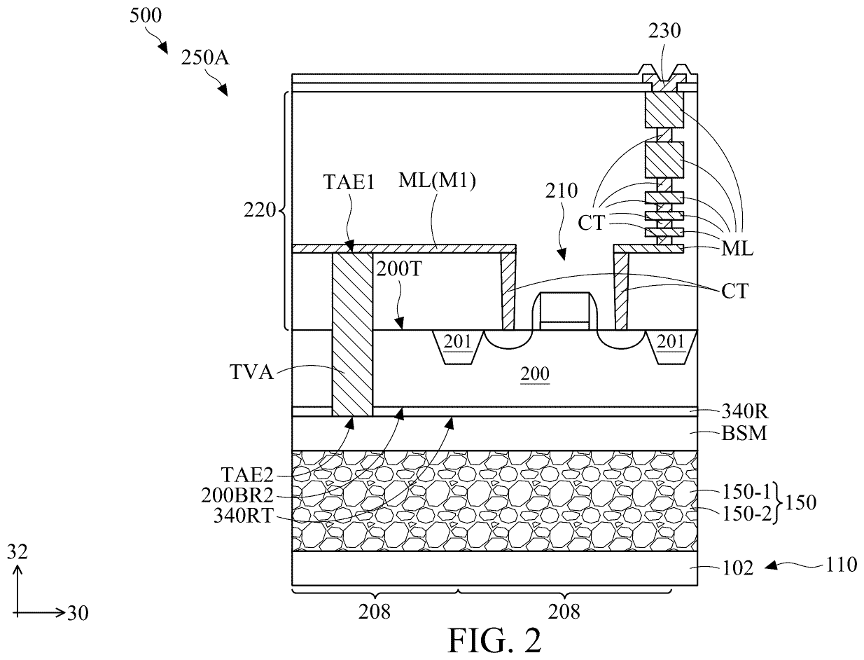

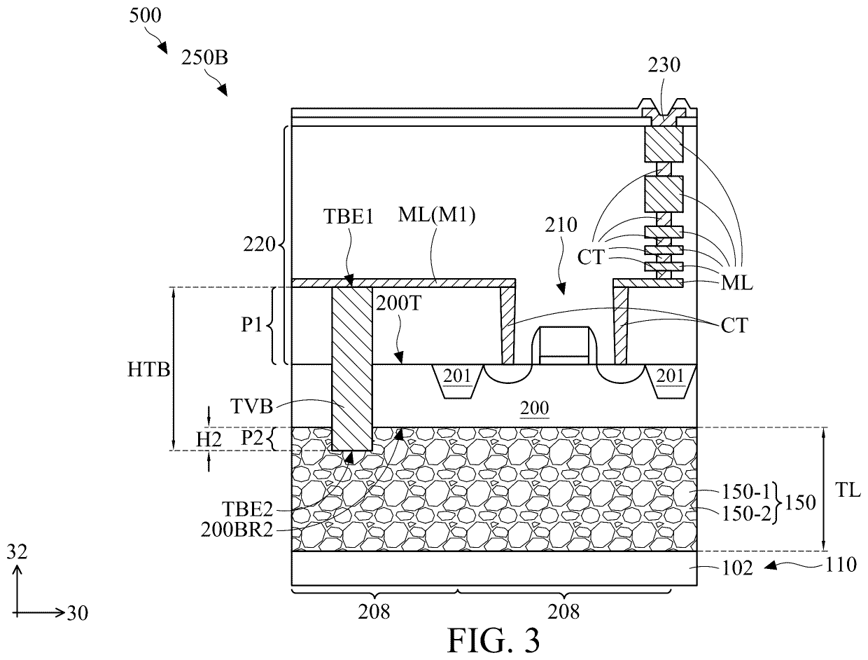

FIG. 1 is a side view of a semiconductor package structure 500 in accordance with some embodiments of the disclosure. The semiconductor package structure 500 (including a semiconductor package structure 500A shown in FIG. 2 and a semiconductor package structure 500B shown in FIG. 3) includes a leadframe 100, a conductive adhesive layer 150 and a semiconductor die 250. In FIG. 1 and the following figures, directions 30 and 31 are defined as horizontal directions (also regarded as the extending directions of conductive layers and/or conductive traces of the semiconductor die 250), and direction 32 is defined as a vertical direction (also regarded as the extending direction of the through via and/or vias of the semiconductor die 250).

As shown in FIG. 1, the leadframe 100 includes a die attach pad (or a die paddle) 102 and leads (or pins) 110. The die attach pad 102 is located at a central region of the semiconductor package structure 500 and supported by four tie bars 104 extending from four corners of the die attach pad 102 to corresponding four corner regions of the semiconductor package structure 500. More specifically, one end of each of the four tie bars 104 terminates at the die attach pad 102 and the other end of each of the four tie bars 104 terminates at the edge of the leadframe 100.

The die attach pad 102 having a top surface 102T and a bottom surface 102B. For example, the top surface 102T of the die attach pad 102 is provided for the semiconductor die 250 mounted on it. The bottom surface 102B of die attach pad 102 of the semiconductor package structure 500 may be exposed for better heat dissipation.

The leads 110 are arranged along and extending outwardly the periphery edges of the die attach pad 102. In some embodiments, the leads 110 are arranged by a predetermined spacing and pitch according to design requirements. In addition, the leads 110 may be arranged in single row or multi rows depending upon various design requirements.

It should be noted that the number of leads 110 and dimension of the semiconductor package structure 500 are only an example and is not a limitation to the present disclosure. In some embodiments, a power ring and/or a ground ring (not shown) may be optionally disposed between the leads 110 and the die attach pad 102.

In some embodiments, the die attach pad 102 and lead 110 may be formed of a conductive material such as copper, aluminum, alloy thereof or any other suitable conductive materials.

As shown in FIG. 1, the semiconductor die (or the semiconductor chip) 250 (including a semiconductor die 250A shown in FIG. 2 and a semiconductor die 250B shown in FIG. 3) is mounted on the top surface 102T of the die attach pad 102 through a conductive adhesive layer 150. In some embodiments, the conductive adhesive layer 150 includes conductive particles (also called fillers) 150-1 dispersing in polymer matrix 150-2.

In some embodiments, the semiconductor die 250 includes a plurality of conductive pads 230, for example, input/output (I/O) pads, disposed along a boundary of an active surface of the semiconductor die 250. In some embodiments, the conductive pads 230 of the semiconductor die 250 are coupled (electrically connected) to the corresponding leads 110 through conductive wires 130. Therefore, the leads 110 may transmit signals (or power) from or to the semiconductor die 250. In some embodiments, the conductive wire 130, for example, a bond wire, includes a copper wire or a gold wire, or other applicable conductive wires.

The semiconductor package structure 500 may further include a molding compound 140. As shown in FIG. 1, the molding compound 140 encapsulates the semiconductor die 200A and the conductive wires 130. In addition, the molding compound 140 may partially encapsulate inner ends of the leads 110 and tie bars 104 and leave outer ends of the leads 110 and tie bars 104 exposed from the molding compound 140. The bottom surface 102B of the die attach pad 102 may be exposed from the molding compound 140 and may be connected to a ground plane and/or heat-dissipating plugs (not shown) in a base (not shown) such as a printed circuit board (PCB). In some embodiments, the molding compound 140 may comprise silicon particle-filled polymer material applied under heat and pressure by transfer molding.

FIG. 2 is a partial enlarged cross-sectional view taken along the line A-A′ of FIG. 1, showing a portion of a semiconductor die 250A and the leadframe 100 of the semiconductor package structure 500A of FIG. 1 in accordance with some embodiments of the disclosure. As shown in FIG. 2, the semiconductor die 250A at least includes a semiconductor substrate 200, a semiconductor device 210 and a through via (TV) TVA.

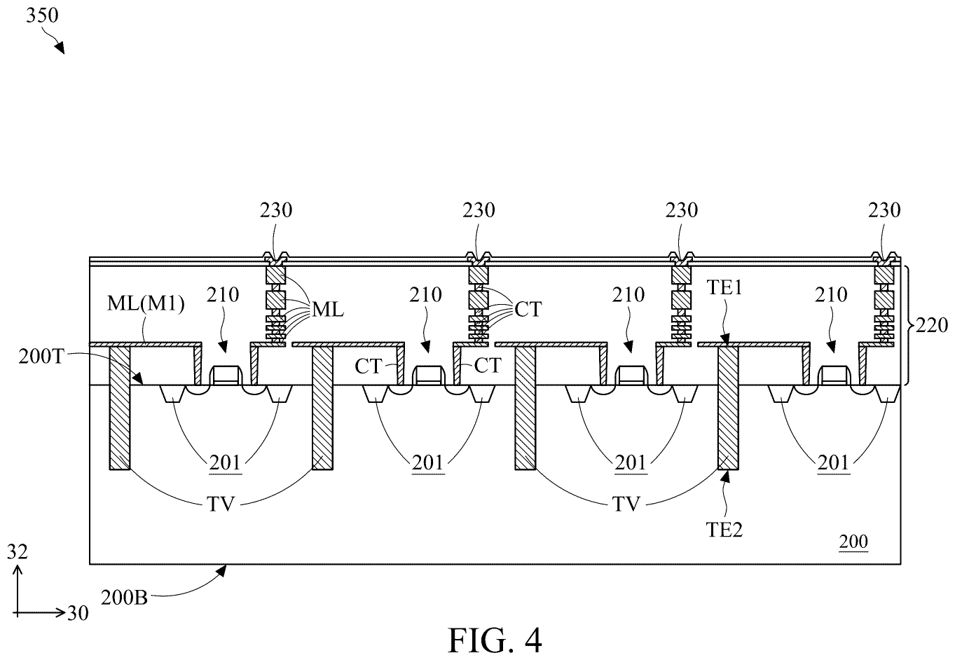

The semiconductor substrate 200 has a first surface 200T and a second surface 200BR2 opposite to the first surface 200T. For example, the first surface 200T and the second surface 200BR2 may serve as the top surface 200T and the bottom surface 200BR2 of the semiconductor substrate 200. The semiconductor substrate 200 may be a portion of a semiconductor wafer (e.g., a semiconductor wafer 350 as shown in FIGS. 4-13). In some embodiments, the semiconductor substrate 200 may include silicon. In alternative embodiments, SiGe, bulk semiconductor, strained semiconductor, compound semiconductor, semiconductor-on-insulator (SOI), and other commonly used semiconductor substrates can be used for the semiconductor substrate 200. In some embodiments, the semiconductor substrate 200 may have a first conductivity type such as P-type, or a second conductivity type such as N-type, depending on requirements.

As shown in FIG. 2, one or more isolation features 201, such as shallow trench isolation (STI) features or local oxidation of silicon (LOCOS) features, may be formed extending from the first surface 200T of the semiconductor substrate 200 into a portion of the semiconductor substrate 200. The isolation features 201 are used to define one or more active regions 208.

The semiconductor device 210 is formed on the semiconductor substrate 200 and in the active region 208. In some embodiments, the semiconductor device 210 includes one or more active components, passive components and circuits. In addition, the isolation features 201 are configured to provide physical and electrical isolation between the semiconductor device 210 and other semiconductor device (not shown) in the active regions 208.

In some embodiments, the semiconductor structure 500 further includes an interconnection structure 220 formed on the semiconductor substrate 200 and the semiconductor device 210. The interconnection structure 220 is disposed on the first surface 200T of the semiconductor substrate 200 and coupled to the semiconductor die 250A. In addition, the interconnection structure 220 are configured coupled (electrically connected) to various terminals of the corresponding semiconductor device 210. In some embodiments, the interconnection structure 220 includes various contacts (and/or vias) CT and conductive traces ML disposed in multilayer interlayer dielectrics (ILD) (not shown). In some embodiments, the contacts (and/or vias) CT and the conductive traces ML include a conductive material, such as copper (Cu), aluminum (Al), tungsten (W), titanium (Ti), titanium nitride (TiN), tantalum (Ta), tantalum nitride (TaN), or another applicable material. In some embodiments, the interlayer dielectrics may include silicon oxide, silicon oxynitride, un-doped silicate glass (USG), borosilicate glass (BSG), phosphoric silicate glass (PSG), borophosphosilicate glass (BPSG), fluorinated silicate glass (FSG), carbon doped oxide, porous carbon doped silicon dioxide, a polymer such as polyimide or silicon oxycarbide polymer (SiOC), or combinations thereof. The contacts and the vias may be alternately arranged with and electrically connected to the conductive traces belong to various conductive layers of the interconnection structure 220. However, it should be noted that the number of contacts (and/or vias) CT and conductive traces ML and the number of interlayer dielectrics shown in FIG. 2 is only an example and is not a limitation to the present invention.

As shown in FIG. 2, the conductive pads 230 are disposed above the first surface 200T of the semiconductor substrate 200. The semiconductor device 210 is disposed below and coupled (electrically connected) to the corresponding conductive pads 230 through the contacts (and/or vias) CT and the conductive traces ML of the interconnection structure 220. In some embodiments, the conductive pads 230 are portions of a topmost conductive layer of the interconnection structure 220. The conductive pads 230 are exposed to openings in a passivation layer (not shown). In some embodiments, the conductive pad 230 includes aluminum (Al) or copper (Cu). However, it should be noted that the number of conductive pads 230 shown in FIGS. 1 and 2 is only an example and is not a limitation to the present invention.

As shown in FIG. 2, the through via TVA is formed above the first surface 200T of the semiconductor substrate 200 and passes through the semiconductor substrate 200 in the direction 32 that is substantially perpendicular to the first surface 200T and the second surface 200BR2 of the semiconductor substrate 200. Therefore, the direction 32 may also be the extending direction of the through via TVA. In some embodiments, the through via TVA has a first protruding portion P1 protruding from the first surface 200T of the semiconductor substrate 200 and extending into a portion of the interconnect structure 220. In other words, the through via TVA is embedded in the semiconductor substrate 200 and the interconnect structure 220.

In some embodiments, the through via TVA is coupled to the semiconductor device 210 through the interconnect structure 220. The through via TVA may have a first end TAE1 and a second end TAE2 opposite to the first end TAE1. In this embodiment, the first end TAE1 of the through via TVA may terminate at one of the conductive layers ML (e.g., the lower metal layer M1) of the interconnect structure 220. The second end TAE2 of the through via TVA may terminate close to the second surface 200BR2 of the semiconductor substrate 200. The through via TVA may be embedded in the interconnect structure 220 and the semiconductor substrate 200. The through via TVA may be further formed protruding from the semiconductor substrate 200. In some embodiments, the second surface 200BR2 of the semiconductor substrate 200 may be close to the second end TAE2 of the through via TVA,

In some embodiments, the conductive pad 230 of the semiconductor die 250A is a power pad or a signal pad. Therefore, the terminal(s) of the semiconductor device 210 for transmitting power or signal may be coupled to the conductive pad 230, but not the through via TVA. In some embodiments, the through via TVA is connected (coupled) to ground. Therefore, the ground terminal of the semiconductor device 210 may be coupled to ground through the through via TVA, but not the conductive pad 230.

In some embodiments as shown in FIG. 2, the semiconductor die 250A may further include a conductive layer (e.g., a bottom side metal layer) BSM disposed on the second surface 200BR2 of the semiconductor substrate 200. In other word, the interconnect structure 220 and the conductive layer BSM are disposed on opposite surfaces of the semiconductor substrate 200. The conductive layer BSM may completely or partially cover the second surface 200BR2 of the semiconductor substrate 200 in the direction 32 that is substantially perpendicular to the first surface 200T (or the second surface 200BR2) of the semiconductor substrate 200. The conductive layer BSM may completely cover the second end TAE2 of the through via TVA in the direction 32. In addition, the conductive adhesive layer BSM is in contact with the second end TAE2 of the through via TVA. In this embodiment, the conductive pad 230 and the conductive layer BSM belong to the topmost and bottommost conductive layers of the semiconductor die 250A. In some embodiments, the conductive layer BSM may include a multi-layer structure composed of titanium (Ti), aluminum (Al), nickel-vanadium (NiV) and gold (Au), or alloys thereof.

In some embodiments as shown in FIG. 2, the semiconductor die 250A may further include a dielectric layer 340R. The dielectric layer 340R may be disposed on the second surface 200BR2. In addition, the dielectric layer 340R may surround the sidewall of the through via TVA close to the second end TAE2. Furthermore, the second end TE2 of the through via TV is little protruding from or flush with a surface 340RT of the dielectric layer 340R. The dielectric layer 340R may server as a protection layer for the through via TVA. In some embodiments, the dielectric layer 340R may include silicon nitride or any other applicable dielectric materials. In some embodiments, the dielectric layer 340R may be formed by a deposition process including chemical vapor deposition (CVD), physical vapor deposition (PVD), atomic layer deposition (ALD), or any other applicable deposition processes.

Since the semiconductor die 250A is mounted on the top surface 102T of the die attach pad 102 through the conductive adhesive layer 150, the conductive layer BSM is located between the through via TVA and the conductive adhesive layer 150. In addition, the conductive layer BSM is in contact with and coupled to the conductive adhesive layer 150. In some embodiments, the through via TVA is coupled to the die attach pad 102 through the conductive adhesive layer 150. Therefore, the die attach pad 102 may serve as a ground pad of the semiconductor package structure 500A.

In the semiconductor package structure 500A, the bottom (the second end TAE2) of the grounded through via TVA terminates at the conductive adhesive layer BSM. In addition, the semiconductor package structure 500A uses the conductive adhesive layer BSM directly coupled between the grounded through via TVA and the conductive adhesive layer 150. Since the contact area between the conductive adhesive layer BSM and the conductive adhesive layer 150 is much larger than the contact area between the conductive adhesive layer BSM and the through via TVA, the conductive adhesive layer BSM may serve as a horizontal extended portion of the vertical extended through via TVA. The conductive adhesive layer BSM may facilitate reducing the resistance of the grounded path from the semiconductor device 210 to the leadframe 100. The electrical performance and reliability of the semiconductor package structure 500A are improved.

FIG. 3 is a partial enlarged cross-sectional view of FIG. 1, showing a portion of a semiconductor die 250B and the leadframe 100 of the semiconductor package structure 500B of FIG. 1 in accordance with some embodiments of the disclosure. Elements of the embodiments hereinafter, that are the same or similar as those previously described with reference to FIGS. 1 and 2, are not repeated for brevity.

As shown in FIGS. 2 and 3, the difference between the semiconductor die 250A and the semiconductor die 250B at least includes that a through via TVB of the semiconductor die 250B further has a second protruding portion P2 protruding from the second surface 200BR2 of the semiconductor substrate 200 and extending into a portion of the conductive adhesive layer 150 in the direction 32 that is substantially perpendicular to the first surface 200T and the second surface 200BR2 of the semiconductor substrate 200. In addition, the semiconductor die 250B is formed without the conductive layer BSM shown in FIG. 1.

As shown in FIG. 3, the second protruding portion P2 of the through via TVB has a height H2 in the direction 32. In some embodiments, the height H2 of the second protruding portion P2 of the through via TVB is less than the total height HTB of the through via TVB in the extending direction (i.e., the direction 32) of the through via TVB, thereby preventing the second protruding portion P2 of the through via TVB from collapsing. For example, the height H2 of the second protruding portion P2 of the through via TVB is between 0.1 and 0.9 times the total height HTB of the through via TVB in the extending direction (i.e., the direction 32) of the through via TVB.

As shown in FIG. 3, the first end TBE1 of the through via TVB terminates at the conductive layer M1 of the interconnect structure 220, and the second end TBE2 of the through via TVB terminates inside the conductive adhesive layer 150. The through via TVB may be embedded in the interconnect structure 220, the semiconductor substrate 200 and the conductive adhesive layer 150. The through via TVB may be formed without passing through the conductive adhesive layer 150. In some embodiments, the height H2 of the second protruding portion P2 of the through via TVB is between 0.1 and 0.9 times the thickness TL of the conductive adhesive layer in the extending direction 32 of the through via TVB.

In the semiconductor die 250B, the through via TVB passing through the semiconductor substrate 200 and protruding into a portion of the conductive adhesive layer 150. The through via TVB has increased area (including the second end TBE2 (i.e., the bottom surface) and a portion of the side surface of the through via TVB) inside and in contact with the conductive adhesive layer 150. Therefore, more conductive particles 150-1 of the conductive adhesive layer 150 are able to be in contact with the through via TVB without using the conductive layer BSM of FIG. 1. The electrical performance and reliability of the semiconductor package structure 500B are further improved.

FIGS. 4, 5, 6, 7, 8, 9, 10, 11, 12 and 13 are enlarged cross-sectional views of intermediate stages of a semiconductor wafer 350 (also an intermediate structure of the semiconductor die 250), showing a method for forming the semiconductor package structure 500 of FIG. 1 in accordance with some embodiments of the disclosure. More specifically, FIGS. 4-13 illustrate intermediate stages of forming the semiconductor die 250A of FIG. 2. Elements of the embodiments hereinafter, that are the same or similar as those previously described with reference to FIGS. 1 to 3, are not repeated for brevity.

As shown in FIG. 4, a semiconductor wafer 350 is provided. In some embodiments, the semiconductor wafer 350 is a fabricated semiconductor wafer. For example, the semiconductor wafer 350 may include a semiconductor substrate 200, one or more semiconductor devices 210 and one or more through vias TV. The semiconductor devices 210 are formed on the semiconductor substrate 200 and in the active regions 208 defined by isolation features 201.

The semiconductor wafer 350 further includes an interconnection structure 220 formed on the semiconductor substrate 200 and the semiconductor devices 210. The interconnection structure 220 is disposed on the first surface 200T of the semiconductor substrate 200 and coupled to the semiconductor wafer 350. In addition, the interconnection structure 220 is configured coupled (electrically connected) to various terminals of the corresponding semiconductor devices 210. It should be noted that the number of contacts (and/or vias) CT and conductive traces ML and the number of interlayer dielectrics shown in FIG. 4 is only an example and is not a limitation to the present invention.

The semiconductor wafer 350 further includes conductive pads 230 disposed above the first surface 200T of the semiconductor substrate 200. The conductive pads 230 are coupled to the corresponding semiconductor device 210 through the contacts (and/or vias) CT and the conductive traces ML of the interconnection structure 220.

As shown in FIG. 4, each of the through vias TV is formed above first surface 200T of the semiconductor substrate 200 and extends into a portion the semiconductor substrate 200 in the direction 32 that is substantially perpendicular to the first surface 200T and the second surface 200B of the semiconductor substrate 200. Therefore, the direction 32 may also be the extending direction of the through via TV. In some embodiments, the through via TV is embedded in the semiconductor substrate 200 and the interconnect structure 220. In some embodiments, each of the through vias TV is coupled to the corresponding semiconductor device 210 through the interconnect structure 220. Each of the through vias TV may have a first end TE1 and a second end TE2 opposite to the first end TE1. In this embodiment, the first end TE1 of the through via TV may terminate at one of the conductive layers ML (e.g., the lower metal layer M1) of the interconnect structure 220. The second end TE2 of the through via TV may terminate inside the semiconductor substrate 200.

In some embodiments, the conductive pads 230 of the semiconductor wafer 350 are power pads or a signal pads. Therefore, the terminal(s) of the semiconductor devices 210 for transmitting power or signal may be coupled to the corresponding conductive pads 230, but not the through vias TV. In some embodiments, the through vias TV are connected (coupled) to ground. Therefore, the ground terminals of the semiconductor devices 210 may be coupled to ground through the corresponding through vias TV, but not the corresponding conductive pads 230.

Next, a trimming process (not shown) may be performed to remove the rounded area at the outer edges of the semiconductor wafer 350 to prevent the semiconductor wafer 350 from breaking during the subsequent thinning process.

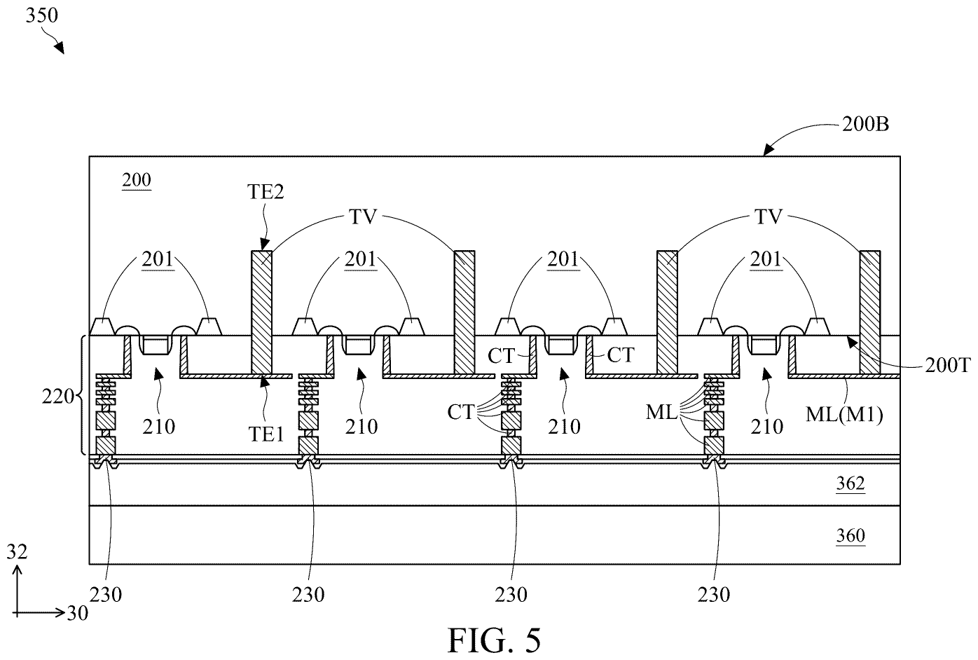

Next, as shown in FIG. 5, the trimmed semiconductor wafer 350 is flipped upside down and disposed on a carrier 360. The first surface 200T of the semiconductor substrate 200 is closer to the carrier 360 than the second surface 200B of the semiconductor substrate 200. In some embodiments, an adhesive layer 362 is coated on the carrier 360 for adhering the semiconductor wafer 350 on the carrier 360. In some embodiments, the material of the carrier 360 includes glass.

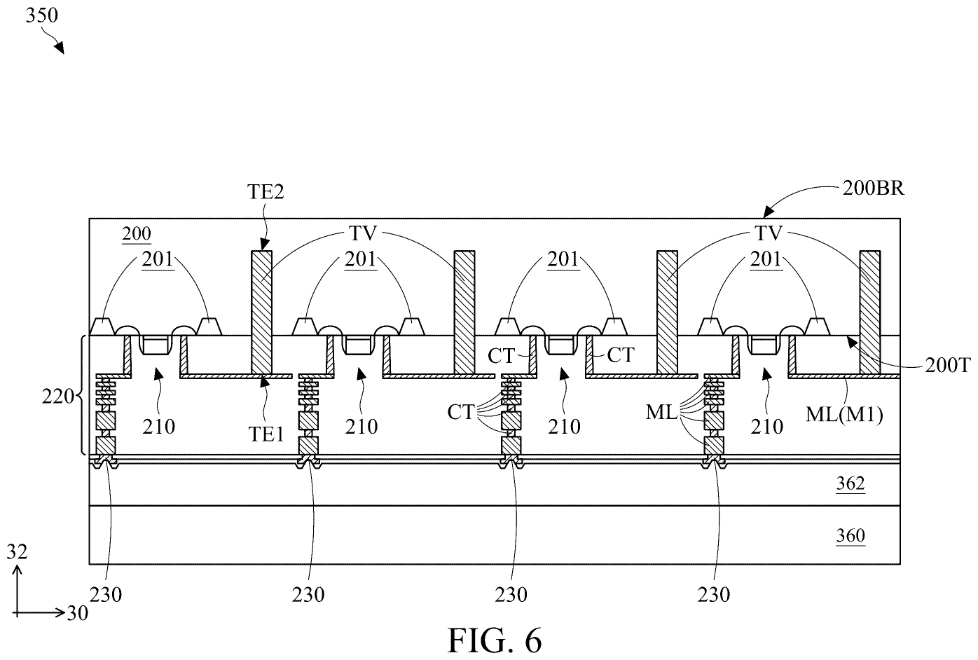

Next, as shown in FIG. 6, a wafer thinning process may be performed to thin down the semiconductor substrate 200 from the second surface 200B to a desired thickness. After performing the wafer thinning process, the bottom surface of the thinned semiconductor die 350 (also the second surface 200BR of the thinned semiconductor substrate 200) is closer to the second ends TE2 of the through vias TV. In some embodiments, the wafer thinning process includes grinding.

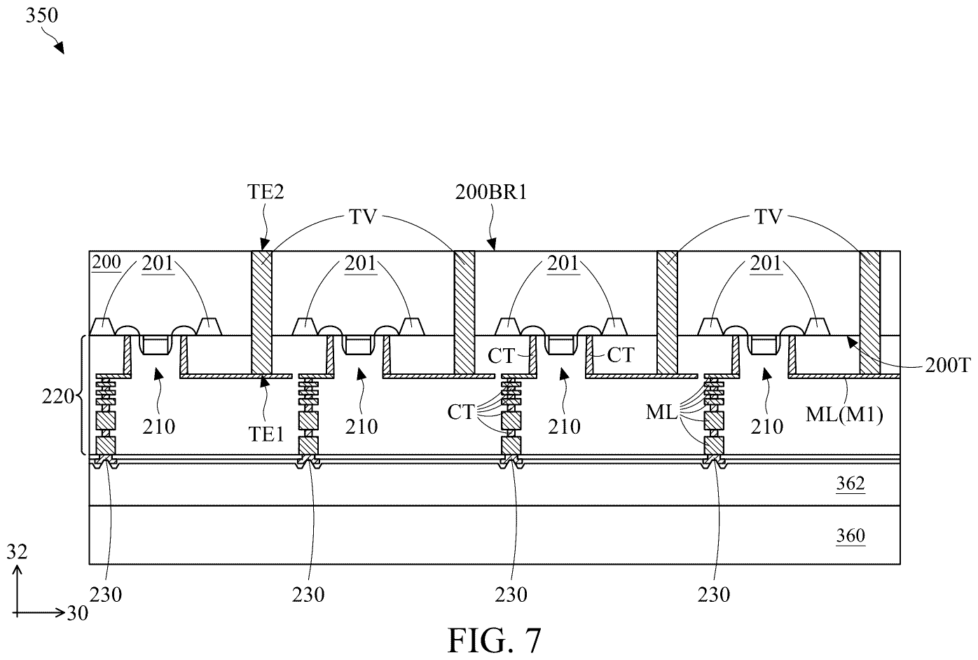

Next, as shown in FIG. 7, a planarization process may be performed to remove a portion of the semiconductor substrate 200 from the second surface 200BR (FIG. 6) of the thinned semiconductor substrate 200 until the second ends TE2 of the through vias TV are exposed from the semiconductor substrate 200. After performing the planarization process, the bottom surface of the planarized semiconductor die 350 (also the second surface 200BR1 of the planarized semiconductor substrate 200) may flush with the second ends TE2 of the through vias TV. In some embodiments, the planarization process includes chemical mechanical planarization (CMP).

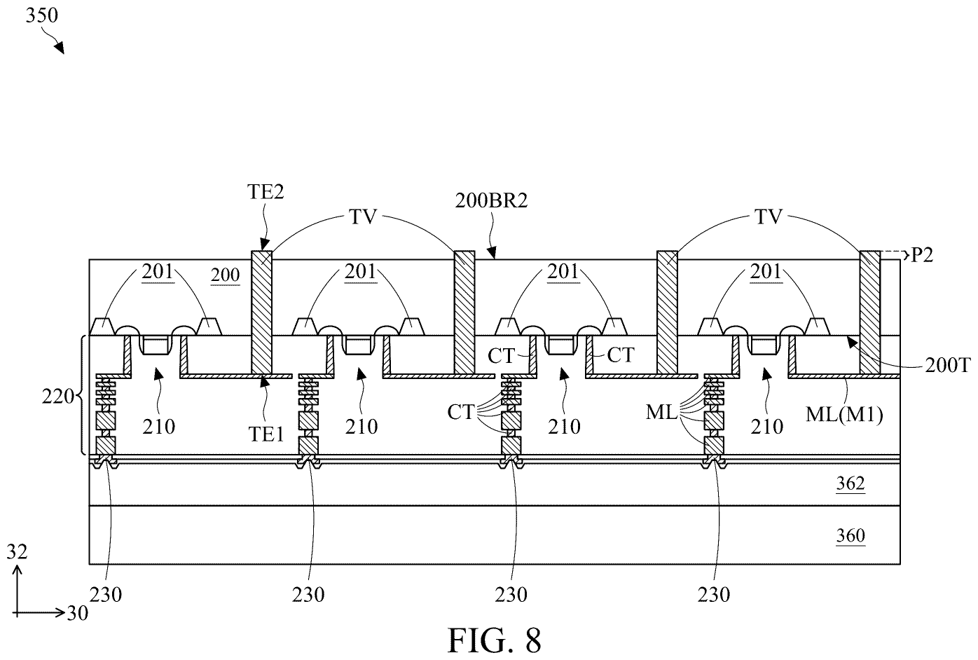

Next, as shown in FIG. 8, a selective etching process may be performed to remove a portion of the semiconductor substrate from the second surface 200BR1 (FIG. 7) of the planarized semiconductor substrate 200 until the through vias TV have protruding portions P2 that protrude from the second surface 200BR2 of the etched semiconductor substrate 200. In some embodiments, the selective etching process includes dry etching.

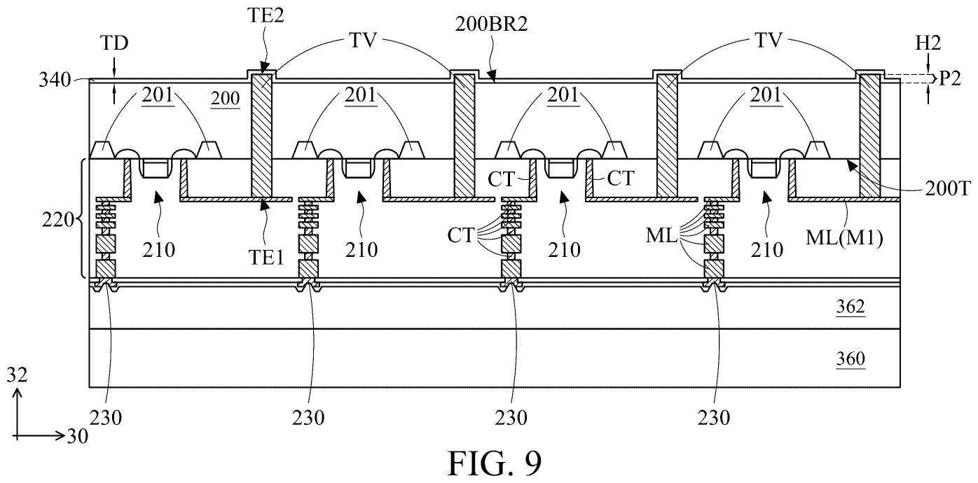

Next, as shown in FIG. 9, a deposition process may be performed to form a dielectric layer 340. The dielectric layer 340 is conformally formed covering the second surface 200BR2 and the portion P2 of the through via TV protruding from the semiconductor substrate 200. In some embodiments, the thickness TD of the dielectric layer 340 is smaller than the height H2 of the second protruding portion P2 in the direction 32. In some embodiments, the dielectric layer 340 may include silicon nitride or any other applicable dielectric materials. In some embodiments, the deposition process may include chemical vapor deposition (CVD), physical vapor deposition (PVD), atomic layer deposition (ALD), or any other applicable deposition processes.

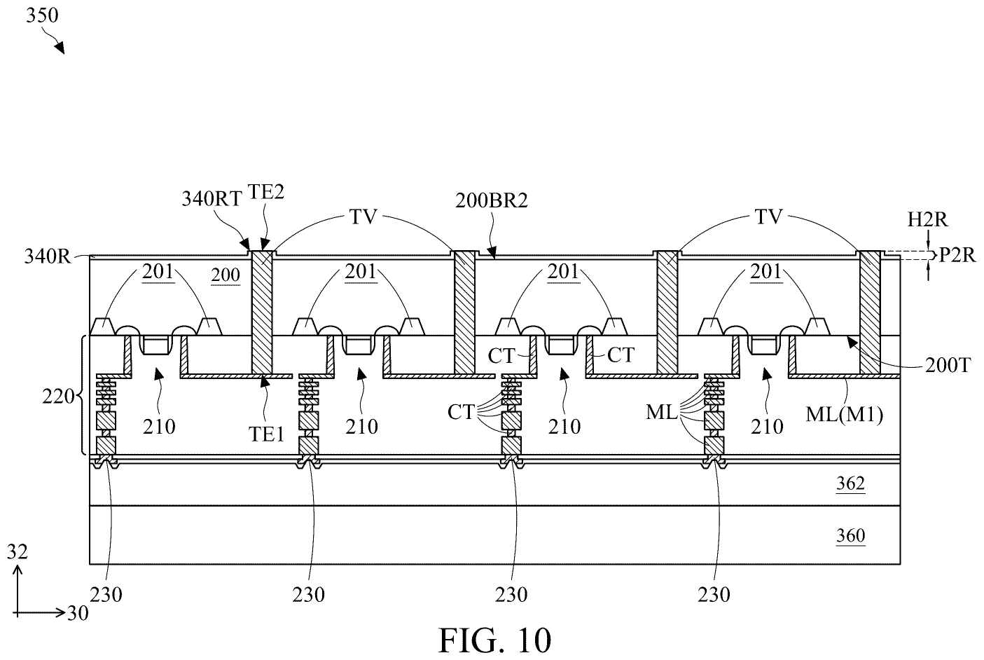

Next, as shown in FIG. 10, a planarization process may be performed to remove a portion of the dielectric layer 340 above the second end TE2 of the protruding portion P2 of the through via TV. In some embodiments, the planarization process may further remove a portion of the through via TV. The remaining protruding portion P2 may be labeled as a protruding portion P2R after performing the planarization process. In some embodiments, the height H2R of the second protruding portion P2R may be equal to the height H2 the second protruding portion P2 (FIG. 9) or less than the height H2 the second protruding portion P2. After performing the planarization process, the remaining dielectric layer 340 may be labeled as the dielectric layer 340R,. After performing the planarization process, the second end TE2 of the through via TV is little higher than or flush with a surface (the top surface) 340RT of the remaining dielectric layer 340R. The dielectric layer 340R may surround the sidewall of the protruding portion P2R. In some embodiments, the planarization process includes chemical mechanical planarization (CMP).

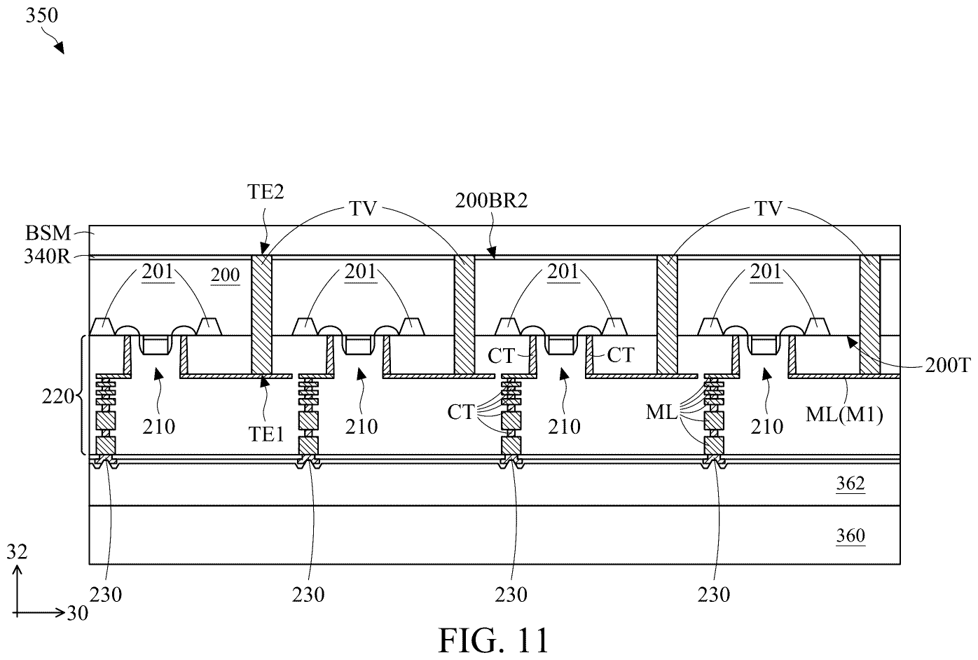

Next, as shown in FIG. 11, a deposition process may be performed to form a conductive layer BSM on the second surface 200B of the semiconductor substrate 200. The conductive layer BSM is in contact with the second end TE2 of the through via TV. In some embodiments, the deposition process include physical vapor deposition (PVD).

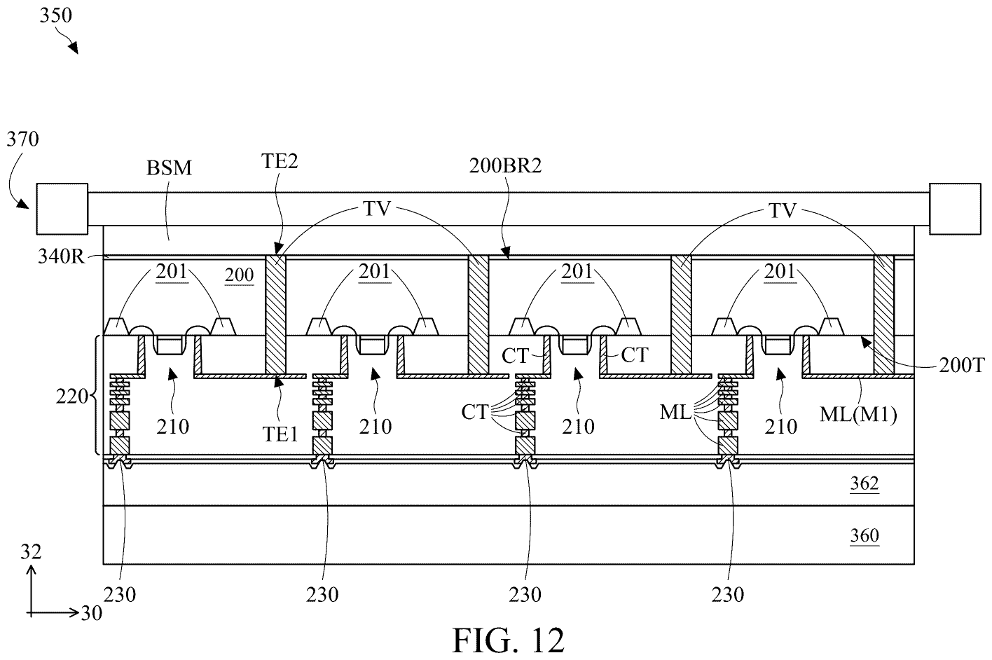

Next, as shown in FIG. 12, the intermediate structure shown in FIG. 11 is attached to another carrier 370. The carrier 370 may be in contact with the conductive layer BSM. In some embodiments, the material of the carrier 370 includes polymer.

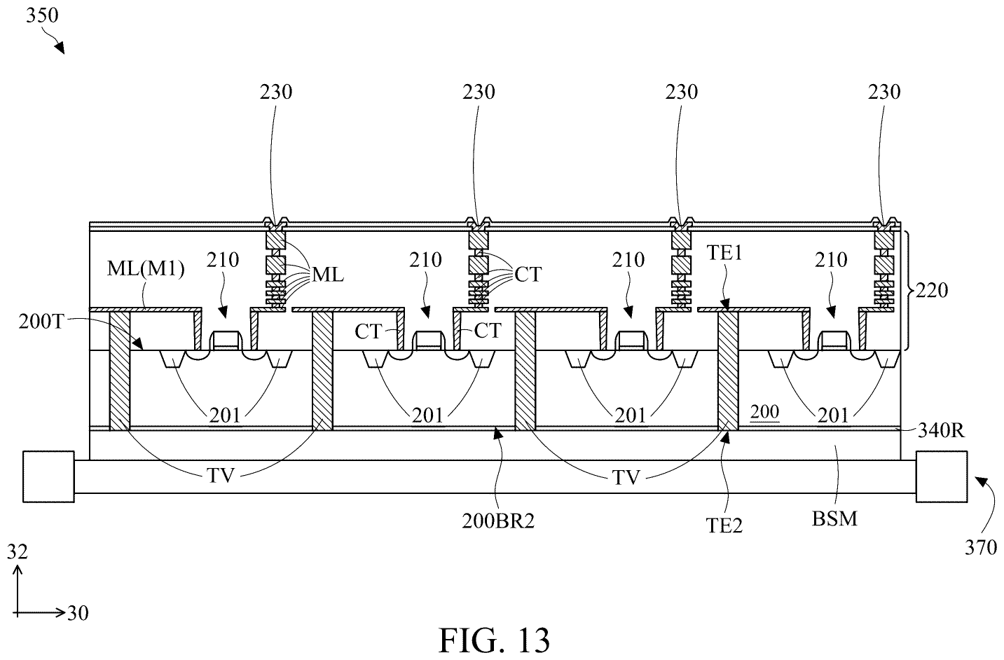

Next, as shown in FIG. 13, the intermediate structure shown in FIG. 11 is flipped again. Next, a removal process is performed to remove the carrier 360 and the adhesive layer 362 from the semiconductor wafer 350.

Next, the intermediate structure shown in FIG. 13 is then subjected to an assembly process. More specifically, the carrier 370 is removed. Next, a singulation process is performed to dice the semiconductor wafer 350 and the conductive layer BSM along scribe lines (not shown) into multiple discrete semiconductor dies 250A (FIG. 2). The through vias in the semiconductor dies 250A are labeled as through vias TVA.

Next, as shown in FIGS. 1 and 2, a conductive adhesive layer 150 is formed on the second surface 200BR2 of the semiconductor substrate 200 of one of the semiconductor die 250A by applying and curing processes. The through via TVA is separated from the conductive adhesive layer 150 through the conductive layer BSM.

Next, as shown in FIGS. 1 and 2, the semiconductor die 250A is mounted on a leadframe 100 including a die attach pad 102 and leads 110. The die attach pad 102 is connected to the conductive adhesive layer 150. In addition, the through via TVA is coupled to the die attach pad 102 through the conductive layer BSM and the conductive adhesive layer 150.

Next, as shown in FIGS. 1 and 2, conductive wires 130 are formed connected between conductive pads 230 of the semiconductor die 250A and the leads 110 the leadframe 100. The conductive pads 230 are disposed on the first surface 200T of the semiconductor substrate 200 and coupled to the semiconductor device 210. After performing the aforementioned processes, the semiconductor package structure 500A including the semiconductor die 250A as shown in FIGS. 1 and 2 is formed.

FIGS. 4-8 also illustrate intermediate stages of a method for forming the semiconductor die 250B of FIG. 3. After performing the processes shown in FIGS.4 and 8, processes similar to those shown in FIG. 12 are performed to attach the intermediate structure shown in FIG. 8 to another carrier that is the same or similar to the carrier 370. The other carrier may be in contact with the through vias TV.

Next, processes similar to those shown in FIG. 13 are performed to remove the carrier 360 from the semiconductor wafer 350.

After performing the processes similar to those shown in FIG. 13, the intermediate structure is then subjected to an assembly process. More specifically, the other carrier is removed. Next, a singulation process is performed to dice the semiconductor wafer 350 without the conductive layer BSM formed on it along scribe lines (not shown) into multiple discrete semiconductor dies 250B (FIG. 3). In the semiconductor dies 250B, the through vias having protruding portions P2 are labeled as through vias TVB.

Next, as shown in FIGS. 1 and 3, a conductive adhesive layer 150 is formed on the second surface 200BR2 of the semiconductor substrate 200 of one of the semiconductor die 250B by applying and curing processes. The conductive adhesive layer 150 surrounds the protruding portion P2 of the through via TVB.

Next, as shown in FIGS. 1 and 3, the semiconductor die 250B is mounted on a leadframe 100 including a die attach pad 102 and leads 110. The die attach pad 102 is connected to the conductive adhesive layer 150. In addition, the through via TVB is coupled to the die attach pad 102 through the conductive adhesive layer 150.

Next, as shown in FIGS. 1 and 3, conductive wires 130 are formed connected between conductive pads 230 of the semiconductor die 250B and the leads 110 the leadframe 100. The conductive pads 230 are disposed on the first surface 200T of the semiconductor substrate 200 and coupled to the semiconductor device 210. After performing the aforementioned processes, the semiconductor package structure 500B including the semiconductor die 250B as shown in FIGS. 1 and 3 is formed.

Embodiments provide a semiconductor package structure. The semiconductor package structure includes a semiconductor die and a conductive adhesive layer. The semiconductor die includes a semiconductor substrate, a semiconductor substrate and a through via. The semiconductor substrate has a first surface and a second surface. The semiconductor device is formed on the first surface of the semiconductor substrate. The through via is formed in such a way that it passes through the semiconductor substrate. The conductive adhesive layer is disposed on the second surface of the semiconductor substrate. The through via is coupled to the conductive adhesive layer.

In some embodiments, the semiconductor die further includes a conductive pad disposed on the first surface of the semiconductor substrate and coupled to the semiconductor device. The semiconductor package structure further includes a leadframe comprising a die attach pad and a lead. The die attach pad is connected to the conductive adhesive layer. The through via is coupled to the die attach pad through the conductive adhesive layer. The lead of the leadframe is coupled to the conductive pad through a conductive wire. In some embodiments, the conductive pad of the semiconductor die is a power pad or a signal pad, and the through via is coupled to ground.

In some embodiments, the through via has a first protruding portion protruding from the first surface of the semiconductor substrate.

In some embodiments, the through via has a second protruding portion protruding from the second surface of the semiconductor substrate in a first direction,

In some embodiments, the semiconductor die further includes an interconnect structure disposed on the first surface of the semiconductor substrate and coupled to the semiconductor device. The through via has a first end and a second end opposite to the first end, the first end of the through via terminates at a conductive layer of the interconnect structure.

In some embodiments, the semiconductor die further includes a conductive layer disposed on the second surface of the semiconductor substrate and located between the through via and the conductive adhesive layer.

In some embodiments, the second end of the through via terminates at the conductive layer, and a sidewall of the through via close to the second end is surrounded by a dielectric layer on the second surface of the semiconductor substrate.

In some embodiments, the conductive layer completely covers the second surface of the semiconductor substrate and the through via.

In some embodiments, the second end of the through via terminates inside the conductive adhesive layer.

In some embodiments, the height of the second protruding portion is between 0.1 and 0.9 times the total height of the through via in the extending direction of the through via.

In some embodiments, the height of the second protruding portion is between 0.1 and 0.9 times the thickness of the conductive adhesive layer in the extending direction of the through via.

Embodiments provide a method for forming a semiconductor package structure. The method includes providing a semiconductor wafer. The semiconductor wafer includes a semiconductor substrate, a semiconductor device and a through via. The semiconductor substrate has a first surface and a second surface. The semiconductor device is formed on the first surface of the semiconductor substrate. The through via extends from above the first surface of the semiconductor substrate into a portion of the semiconductor substrate. The method further includes removing a portion of the semiconductor substrate from the second surface until the through via has a protruding portion that protrudes from the semiconductor substrate. The method further includes forming a conductive adhesive layer on the second surface of the semiconductor substrate.

In some embodiments, the method further includes removing a portion of the semiconductor substrate from the second surface until the through via is exposed from the semiconductor substrate before removing a portion of the semiconductor substrate from the second surface.

In some embodiments, the second surface of the semiconductor substrate is flush with the end of the through via.

In some embodiments, the conductive adhesive layer is coupled to the through via.

In some embodiments, the conductive adhesive layer surrounds the protruding portion of the through via.

In some embodiments, the method further includes forming a dielectric layer covering the second surface and the portion of the through via protruding from the semiconductor substrate. The method further includes removing a portion of the dielectric layer above the end of the protruding portion of the through via.

In some embodiments, the method further includes forming a conductive layer on the second surface of the semiconductor substrate.

In some embodiments, the through via is separated from the conductive adhesive layer through the conductive layer.

In some embodiments, the method further includes dicing the semiconductor wafer into discrete semiconductor dies. The method further includes mounting one the semiconductor dies on a leadframe. The leadframe includes a die attach pad and a lead. The die attach pad is connected to the conductive adhesive layer. The through via is coupled to the die attach pad through the conductive adhesive layer. The method further includes forming a conductive wire connected between the conductive pad of the semiconductor die and the lead of the leadframe. The conductive pad is disposed on the first surface of the semiconductor substrate and coupled to the semiconductor device.

In the semiconductor package structure, the ground terminal of the semiconductor die (e.g., the semiconductor die 210) is coupled to a through via (e.g., the through via TVA or TVB). In some embodiments, the grounded through via (e.g., the through via TVA) has the second protruding portion (e.g., the second protruding portion P2R) surrounded by a dielectric thin layer (e.g., the dielectric layer 340R), leaving the exposed end (e.g., the second end TAE2) to connected to a conductive layer (e.g., the conductive layer BSM). The conductive layer fully covers the second surface (e.g., the second surface 200BR2) of the semiconductor substrate (e.g., the semiconductor substrate 200) and disposed between the conductive layer and the conductive adhesive layer (e.g., the conductive adhesive layer 150). The through via is coupled to the conductive adhesive layer through the conductive layer which has an increased contact area with the conductive adhesive layer. Alternatively, the second protruding portion (e.g., the second protruding portion P2) of the through via (e.g., the through via TVB) is in contact with and surrounded by the conductive adhesive layer. More conductive particles (e.g., the conductive particles 150-1) inside the conductive adhesive layer may be in contact with the end surface (e.g., the second end TBE2) and the side surface of the second protruding portion of the through via. The electrical performance and reliability of the semiconductor package structure can be improved.

While the disclosure has been described by way of example and in terms of the preferred embodiments, it should be understood that the disclosure is not limited to the disclosed embodiments. On the contrary, it is intended to cover various modifications and similar arrangements (as would be apparent to those skilled in the art). Therefore, the scope of the appended claims should be accorded the broadest interpretation so as to encompass all such modifications and similar arrangements.

What is claimed is:

1. A semiconductor package structure, comprising:
a semiconductor die, comprising:
a semiconductor substrate having a first surface and a second surface;
a semiconductor device formed on the first surface of the semiconductor substrate; and
a through via formed in such a way that it passes through the semiconductor substrate; and
a conductive adhesive layer disposed on the second surface of the semiconductor substrate, wherein the through via is coupled to the conductive adhesive layer.

2. The semiconductor package structure as claimed in claim 1, wherein the semiconductor die further comprises:
a conductive pad disposed on the first surface of the semiconductor substrate and coupled to the semiconductor device; and wherein the semiconductor package structure further comprises:
a leadframe comprising a die attach pad and a lead, wherein:
the semiconductor die attach pad is connected to the conductive adhesive layer, wherein the through via is coupled to the die attach pad through the conductive adhesive layer, and
the lead of the leadframe is coupled to the conductive pad through a conductive wire.

3. The semiconductor package structure as claimed in claim 2, wherein the conductive pad of the semiconductor die is a power pad or a signal pad, and the through via is coupled to ground.

4. The semiconductor package structure as claimed in claim 2, wherein the through via has a first protruding portion protruding from the first surface of the semiconductor substrate.

5. The semiconductor package structure as claimed in claim 4, wherein the through via has a second protruding portion protruding from the second surface of the semiconductor substrate in a first direction.

6. The semiconductor package structure as claimed in claim 2, wherein the semiconductor die further comprises:
an interconnect structure disposed on the first surface of the semiconductor substrate and coupled to the semiconductor device, wherein the through via has a first end and a second end opposite to the first end, and the first end of the through via terminates at a conductive layer of the interconnect structure.

7. The semiconductor package structure as claimed in claim 1, wherein the semiconductor die further comprises:
a conductive layer disposed on the second surface of the semiconductor substrate and located between the through via and the conductive adhesive layer.

8. The semiconductor package structure as claimed in claim 7, wherein the second end of the through via terminates at the conductive layer, and a sidewall of the through via close to the second end is surrounded by a dielectric layer on the second surface of the semiconductor substrate.

9. The semiconductor package structure as claimed in claim 6, wherein the second end of the through via terminates inside the conductive adhesive layer.

10. The semiconductor package structure as claimed in claim 9, wherein a height of the second protruding portion is between 0.1 and 0.9 times a total height of the through via in an extending direction of the through via.

11. The semiconductor package structure as claimed in claim 9, wherein a height of the second protruding portion is between 0.1 and 0.9 times a thickness of the conductive adhesive layer in an extending direction of the through via.

12. A method for forming a semiconductor package structure, comprising:
providing a semiconductor wafer, wherein the semiconductor wafer comprises:
a semiconductor substrate having a first surface and a second surface;
a semiconductor device formed on the first surface of the semiconductor substrate; and
a through via extending from above the first surface of the semiconductor substrate into a portion of the semiconductor substrate;
removing a portion of the semiconductor substrate from the second surface until the through via has a protruding portion that protrudes from the semiconductor substrate; and
forming a conductive adhesive layer on the second surface of the semiconductor substrate.

13. The method for forming a semiconductor package structure as claimed in claim 12, further comprising:
removing a portion of the semiconductor substrate from the second surface until the through via is exposed from the semiconductor substrate before removing a portion of the semiconductor substrate from the second surface.

14. The method for forming a semiconductor package structure as claimed in claim 13, wherein the second surface of the semiconductor substrate is flush with an end of the through via.

15. The method for forming a semiconductor package structure as claimed in claim 14, wherein the conductive adhesive layer is coupled to the through via.

16. The method for forming a semiconductor package structure as claimed in claim 12, wherein the conductive adhesive layer surrounds the protruding portion of the through via.

17. The method for forming a semiconductor package structure as claimed in claim 12, further comprising:
forming a dielectric layer covering the second surface and the protruding portion of the through via; and
removing a portion of the dielectric layer above an end of the protruding portion of the through via.

18. The method for forming a semiconductor package structure as claimed in claim 17, further comprising:
forming a conductive layer on the second surface of the semiconductor substrate.

19. The method for forming a semiconductor package structure as claimed in claim 18, wherein the through via is separated from the conductive adhesive layer through the conductive layer.

20. The method for forming a semiconductor package structure as claimed in claim 13, further comprising:
dicing the semiconductor wafer into discrete semiconductor dies; and
mounting one the semiconductor dies on a leadframe, wherein the leadframe comprises a die attach pad and a lead, wherein:
the die attach pad is connected to the conductive adhesive layer, wherein the through via is coupled to the die attach pad through the conductive adhesive layer, and
forming a conductive wire connected between a conductive pad of the semiconductor die and the lead of the leadframe, wherein the conductive pad is disposed on the first surface of the semiconductor substrate and coupled to the semiconductor device.
